(19) United States
(12) Patent Application Publication
(10) Pub. No.: US 2025/0224663 A1
(43) Pub. Date: Jul. 10, 2025

(54) REFLECTION-TYPE MASK BLANK, REFLECTION-TYPE MASK, AND METHOD FOR MANUFACTURING REFLECTION-TYPE MASK

(71) Applicant: AGC Inc., Tokyo (JP)

(72) Inventors: Masayoshi MIZOGUCHI, Koriyama-shi (JP); Takeshi TOMIZAWA, Koriyama-shi (JP); Takahira MIYAGI, Koriyama-shi (JP); Naoyuki MIURA, Koriyama-shi (JP); Taiga FUDETANI, Koriyama-shi (JP); Yusuke ONO, Koriyama-shi (JP)

(73) Assignee: AGC Inc., Tokyo (JP)

(21) Appl. No.: 19/090,825

(22) Filed: Mar. 26, 2025

Related U.S. Application Data
(63) Continuation of application No. PCT/JP2023/037235, filed on Oct. 13, 2023.

(30) Foreign Application Priority Data
Oct. 21, 2022 (JP) 2022-169168
May 25, 2023 (JP) 2023-085943

(51) Int. Cl. G03F 1/24; G03F 1/48; G03F 1/54; G03F 1/80

(52) U.S. Cl. CPC G03F 1/24; G03F 1/48; G03F 1/54; G03F 1/80

(57) ABSTRACT

Provided is a reflective mask blank whose surface on the back side where a conductive film is arranged is excellent in strength. A reflective mask blank includes: a substrate; a conductive film arranged on one surface side of the substrate; a protection film arranged on a side of the conductive film opposite to the substrate; a multilayer reflective film to reflect EUV light, arranged on the other surface side of the substrate; and an absorber film arranged on a side of the multilayer reflective film opposite to the substrate, wherein the conductive film and the protection film have different compositions, wherein the conductive film contains a first element selected from the group consisting of chromium and tantalum, wherein the protection film contains chromium and at least one second element selected from the group consisting of boron, carbon, nitrogen and oxygen, wherein the protection film has a thickness of 2 nm or more, and wherein, in X-ray photoelectron spectroscopy analysis of the protection film, a peak corresponding to an 2p_{3/2} orbital of chromium appears at 576.7 eV or lower.

### TECHNICAL FIELD

The present invention relates to a reflective mask used for EUV (Extreme Ultra Violet) exposure during an exposure process in semiconductor manufacturing, its production method, and a reflective mask blank as an original plate of a reflective mask.

### BACKGROUND ART

Recent years have seen studies of EUV lithography, which uses EUV light with a center wavelength of about 13.5 nm as a light source, for further miniaturization of semiconductor devices.

In EUV exposure, a reflective optical system and a reflective mask are used due to the characteristics of EUV light. The reflective mask has a multilayer reflective film provided on a substrate to reflect EUV light and a patterned absorber film provided on the multilayer reflective film to absorb EUV light.

The EUV light incident on the reflective mask from an illumination optical system of exposure equipment is reflected in areas (opening areas) where the absorber film is not present and is absorbed in areas (non-opening areas) where the absorber film is present. Consequently, the mask pattern is transferred as a resist pattern onto a wafer through a reductive projection optical system of exposure equipment, and then, the subsequent processing is carried out.

On the other hand, in the reflective mask and a reflective mask blank before patterning of the absorber film, it is often the case that a conductive film for electrostatic chucking is provided on a surface of the substrate opposite to the absorber film.

For example, Patent Document 1 discloses a reflective mask blank such as a reflective mask blank having a conductive film formed using a material containing tantalum.

### PRIOR ART DOCUMENTS

### Patent Documents

Patent Document 1: JP-A-2013-225662

### DISCLOSURE OF INVENTION

### Technical Problem

The reflective mask and the reflective mask blank, each having a conductive film as mentioned above, are repeatedly subjected to adsorption by electrostatic chucking and release from the adsorption state during their production and use. There are cases in which, at the time of adsorption and release from the adsorption state, a surface of the reflective mask blank on the back side where the conductive film is arranged is brought into contact with and rubbed against a member for electrostatic chucking. Hereinafter, the surface of the reflective mask blank on the back side where the conductive film is arranged is occasionally simply referred to as the “back side surface”. The back side refers to, with respect to the substrate, a side of the reflective mask blank where the conductive film is arranged.

In view of the fact that, when the strength of the back side surface is low, particles may be generated from the conductive film, the back side surface is required to have high strength.

The present inventors have assessed the conductive film disclosed in Patent Document 1 and have found that there is room for improvement in the strength of a surface of the conductive film opposite to the substrate.

In view of the foregoing, it is an object of the present invention to provide a reflective mask blank whose surface on the back side where a conductive film is arranged is excellent in strength.

It is also an object of the present invention to provide a method for producing a reflective mask using the reflective mask blank and to provide a reflective mask.

### Solution to Problem

As a result of intensive studies on the above-mentioned problems, the present inventors have found that it is possible to solve the above-mentioned problems when a protection film is formed on a conductive film and shows, in X-ray photoelectron spectroscopy analysis, a peak for a predetermined binding energy.

Namely, the present inventors have found the following solutions to the above-mentioned problems.
[1] A reflective mask blank, comprising:
a substrate;
a conductive film arranged on one surface side of the substrate;
a protection film arranged on a side of the conductive film opposite to the substrate;
a multilayer reflective film to reflect EUV light, arranged on the other surface side of the substrate; and
an absorber film arranged on a side of the multilayer reflective film opposite to the substrate,
wherein the conductive film and the protection film have different compositions,
wherein the conductive film contains a first element selected from the group consisting of chromium and tantalum,
wherein the protection film contains chromium and at least one second element selected from the group consisting of boron, carbon, nitrogen and oxygen,
wherein the protection film has a thickness of 2 nm or more, and
wherein, in X-ray photoelectron spectroscopy analysis of the protection film, a peak corresponding to the 2p_{3/2} orbital of chromium appears at 576.7 eV or lower.
[2] A reflective mask blank, comprising:
a substrate;
a conductive film arranged on one surface side of the substrate;
a protection film arranged on a side of the conductive film opposite to the substrate;
a multilayer reflective film to reflect EUV light, arranged on the other surface side of the substrate; and
an absorber film arranged on a side of the multilayer reflective film opposite to the substrate,
wherein the conductive film and the protection film have different compositions,
wherein the conductive film contains a first element selected from the group consisting of chromium and tantalum,
wherein the protection film contains a first element A selected from the group consisting of chromium and tantalum and at least one second element selected from the group consisting of boron, carbon, nitrogen and oxygen,
wherein the protection film has a thickness of 5 nm or more, and
wherein, in X-ray photoelectron spectroscopy analysis of the protection film, a peak corresponding to the 2p_{3/2} orbital of chromium appears at 576.7 eV or lower, or a peak corresponding to the 4f_{5/2} orbital of tantalum appears at 23.8 eV or higher.
[3] The reflective mask blank according to [1] or [2],
wherein the protection film contains chromium, and
wherein the content of the second element in the protection film is 10 to 65 atomic % to all atoms in the protection film as determined by X-ray photoelectron spectroscopy analysis.
[4] The reflective mask blank according to [3], wherein the content of the second element in the protection film is 63 atomic % or less to all atoms in the protection film as determined by X-ray photoelectron spectroscopy analysis.
[5] The reflective mask blank according to [3], wherein the content of the second element in the protection film is 40 atomic % or less to all atoms in the protection film as determined by X-ray photoelectron spectroscopy analysis.
[6] The reflective mask blank according to [2],
wherein the protection film contains tantalum, and
wherein the content of the second element in the protection film is 20 atomic % or more to all atoms in the protection film as determined by X-ray photoelectron spectroscopy analysis.
[7] The reflective mask blank according to [6], wherein the content of the second element in the protection film is 20 to 90 atomic % to all atoms in the protection film as determined by X-ray photoelectron spectroscopy analysis.
[8] The reflective mask blank according to any one of [1] to [7], wherein the second element contained in the protection film includes at least oxygen.
[9] The reflective mask blank according to any one of [1] to [8], wherein the conductive film contains at least nitrogen as a second element.
[10] The reflective mask blank according to any one of [1] to [9], wherein the protection film has a surface roughness Rq of 0.450 nm or less.
[11] The reflective mask blank according to any one of [1] to [10], wherein the protection film has a thickness of 7 to 50 nm.
[12] The reflective mask blank according to any one of [1] to [11], wherein the protection film has a thickness of 10 to 50 nm.
[13] The reflective mask blank according to any one of [1] to [12], wherein a laminated film of the protection film and the conductive film has a volume resistivity of 2.0×10⁻² Ω·cm or lower.
[14] The reflective mask blank according to any one of [1] to [13], wherein a laminated film of the protection film and the conductive film has a volume resistivity of 2.0×10⁻⁴ Ω·cm or lower.
[15] The reflective mask blank according to any one of [1] to [14], wherein the protection film has a surface hardness of 10.0 GPa or higher.
[16] A reflective mask comprising an absorber film pattern formed by patterning the absorber film of the reflective mask blank as defined in any one of [1] to [15].
[17] A method for producing a reflective mask, comprising patterning the absorber film of the reflective mask blank as defined in any one of [1] to [15].
[18] A method for producing the reflective mask blank as defined in [1] or [2], comprising:
forming the conductive film on one surface of the substrate; and
forming the protection film on a surface of the conductive film opposite to the substrate,
wherein the formation of the protection film is performed in the presence of at least one type of gas selected from the group consisting of oxygen gas and nitrogen gas.
[19] The method for producing the reflective mask blank according to [18],
wherein the protection film is formed using a sputtering target,
wherein the sputtering target contains a first element A selected from the group consisting of chromium and tantalum, and
wherein a surface of the sputtering target is mainly in a metallic state.

### Advantageous Effects of Invention

According to the present invention, it is possible to provide a reflective mask blank whose surface on the back side where a conductive film is arranged is excellent in strength.

It is also possible according to the present invention to provide a method for producing a reflective mask using the reflective mask blank and to provide a reflective mask.

### BRIEF DESCRIPTION OF DRAWINGS

FIG. 1 is a schematic view illustrating an embodiment example of the reflective mask blank of the present invention.

FIG. 2 is a schematic view illustrating an example of a process for producing a reflective mask using the reflective mask blank of the present invention.

### DESCRIPTION OF EMBODIMENTS

Hereinafter, the present invention will be described in detail below.

Although the following description of the constituent features of the present invention may be made based on typical embodiments of the present invention, the present invention is not limited to these embodiments.

The meaning of each expression in the present specification is as follows.

In the present specification, a numerical range expressed using “to” means a range including numerical values described before and after “to” as lower and upper limits.

In the present specification, elements such as boron, carbon, nitrogen, oxygen, silicon, titanium, chromium, zirconium, niobium, molybdenum, ruthenium, rhodium, palladium, tantalum, iridium and the like may be respectively expressed by their corresponding chemical symbols (B, C, N, O, Si, Ti, Cr, Zr, Nb, Mo, Ru, Rh, Pd, Ta, Ir etc.).

### Reflective Mask Blank

One embodiment of the reflective mask blank of the present invention includes: a substrate; a conductive film arranged on one surface side of the substrate; a protection film arranged on a side of the conductive film opposite to the substrate; a multilayer reflective film to reflect EUV, arranged on the other surface side of the substrate; and an absorber film arranged on a side of the multilayer reflective film opposite to the substrate.

In this embodiment, the conductive film and the protection film have different compositions. The conductive film contains a first element selected from the group consisting of Cr and Ta.

The protection film contains chromium and at least one second element selected from the group consisting of B, C, N and O, and has a thickness of 2 nm or more.

Further, the protection film, when analyzed by X-ray photoelectron spectroscopy (XPS), shows a peak corresponding to the 2p_{3/2} orbital of Cr at 576.7 eV or lower.

Another embodiment of the reflective mask blank of the present invention includes: a substrate; a conductive film arranged on one surface side of the substrate; a protection film arranged on a side of the conductive film opposite to the substrate; a multilayer reflective film to reflect EUV light, arranged on the other surface side of the substrate; and an absorber film arranged on a side of the multilayer reflective film opposite to the substrate.

In this embodiment, the conductive film and the protection film have different compositions. The conductive film contains a first element selected from the group consisting of Cr and Ta.

The protection film contains a first element A selected from the group consisting of Cr and Ta and at least one second element selected from the group consisting of B, C, N and O, and has a thickness of 2 nm or more.

Further, the protection film, when analyzed by X-ray photoelectron spectroscopy (XPS), shows a peak corresponding to the 2p_{3/2} orbital of Cr at 576.7 eV or lower or a peak corresponding to the 4f_{5/2} orbital of tantalum at 23.8 eV or higher.

The reflective mask blank of the present invention will be described in more detail below with reference to the drawings.

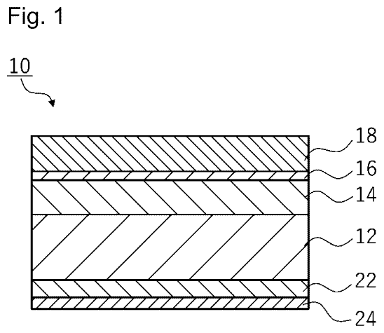

FIG. 1 is a cross-sectional view illustrating an embodiment example of the reflective mask blank of the present invention. A reflective mask blank 10 shown in FIG. 1 has a protection film 24, a conductive film 22, a substrate 12, a multilayer reflective film 14 and an absorber film 18 in this order.

As shown in FIG. 1, the reflective mask blank 10 may have a multilayer reflective film-protection film 16 between the multilayer reflective film 14 and the absorber film 18.

Here, the protection film 24 and the conductive film 22 satisfy any of the above-mentioned requirements.

The one embodiment of the reflective mask blank of the present invention is characterized in that the protection film satisfying the above-mentioned predetermined requirements is arranged on the side of the conductive film opposite to the substrate.

The protection film is considered to have high rigidity as the protection film contains Cr and at least one second element selected from the group consisting of B, C, N and O as mentioned above. On the other hand, the protection film is considered to have a certain level of toughness as the peak corresponding to the 2p_{3/2} orbital of Cr appears at a predetermined value or lower. It is further considered that, as the thickness of the protection film is 2 nm or more, the protection film itself is difficult to bend. As a result, the one embodiment of the reflective mask blank of the present invention has a back side surface excellent in strength.

The another embodiment of the reflective mask blank of the present invention is also characterized in that the protection film satisfying the above-mentioned predetermined requirements is arranged on the side of the conductive film opposite to the substrate. The protection film is considered to have high rigidity as the protection film contains a first element A selected from the group consisting of Cr and Ta and at least one second element selected from the group consisting of B, C, N and O as mentioned above. On the other hand, the protection film is considered to have a certain level of toughness when the peak corresponding to the 2p_{3/2} orbital of Cr appears at a predetermined value or lower. When the peak corresponding to the 4f_{5/2} orbital of Ta appears at a predetermined value or higher, the protective film is considered to have high hardness. It is further considered that, as the thickness of the protection film is 2 nm or more, the protection film itself is difficult to bend. As a result, the another embodiment of the reflective mask blank of the present invention also has a back side surface excellent in strength.

In the reflective mask blank 10 shown in FIG. 1, the protection film 24 and the conductive film 22 are arranged on the entire main surface of the substrate 12, but may alternatively be arranged on a portion of the substrate 12.

The configuration of the reflective mask blank of the present invention will be now described below.

Hereinafter, excellent strength of the back side surface may be simply referred to as “excellent surface strength”.

### Substrate

The substrate in the reflective mask blank of the present invention is preferably low in thermal expansion coefficient. When the thermal expansion coefficient of the substrate is low, it is possible to suppress a distortion in a pattern of the absorber film caused due to heat by EUV exposure.

The thermal expansion coefficient of the substrate at 20° C. is preferably 0±1.0×10⁻⁷/° C., more preferably 0±0.3×10⁻⁷/° C.

As a material having a low thermal expansion coefficient, SiO₂—TiO₂ glass may be mentioned. The material of the substrate is however not limited to this glass. Substrates of crystallized glass with a B-quartz solid solution precipitated therein, silica glass, metallic silicon, metal and the like are also usable.

The SiO₂—TiO₂ glass is preferably silica glass having a SiO₂ content of 90 to 95 mass % and a TiO₂ content of 5 to 10 mass %. When the TiO₂ content is 5 to 10 mass %, the linear expansion coefficient of the glass at around room temperature is substantially zero so that there occurs almost no dimensional change at around room temperature. The SiO₂—TiO₂ glass may contain a trace component other than SiO₂ and TiO₂.

The surface (hereinafter also referred to as “first main surface”) of the substrate on which the multilayer reflective film is arranged is preferably high in surface smoothness. The surface smoothness of the first main surface can be evaluated by surface roughness. The surface roughness of the first main surface is preferably 0.15 nm or less in terms of the root mean square roughness Rq. Here, the surface roughness can be measured with an atomic force microscope; and the surface roughness will be explained as the root mean square roughness Rq according to JIS B0601.

From the viewpoint of improving the pattern transfer accuracy and position accuracy of a reflective mask obtained from the reflective mask blank, the first main surface is preferably surface-processed to a certain level of flatness. The flatness of the substrate in a predetermined region (for example, a 132 mm×132 mm region) of the first main surface is preferably 100 nm or less, more preferably 50 nm or less, still more preferably 30 nm or less. The flatness can be measured with a flatness tester manufactured by Fujinon Corporation.

The size and thickness of the substrate are determined as appropriate according to the design value and the like of the mask. For example, the substrate may be provided with an external shape of 6 inches (152 mm) square and a thickness of 0.25 inches (6.3 mm).

Furthermore, the substrate is preferably high in rigidity from the viewpoint of preventing the film (multilayer reflective film, absorber film or the like) formed on the substrate from being deformed due to film stress. For example, the Young's modulus of the substrate is preferably 65 GPa or higher.

### Multilayer Reflective Film

The multilayer reflective film in the reflective mask blank of the present invention is not particularly limited so far as it has desired characteristics as a reflective film of the EUV mask blank. The multilayer reflective film is preferably high in EUV light reflectance. More specifically, when a surface of the multilayer reflective film is irradiated with EUV light at an incident angle of 6°, the maximum value of the reflectance to EUV light with a wavelength in the vicinity of 13.5 nm is preferably 60% or higher, more preferably 65% or higher. Even in the case where the protection film is laminated on the multilayer reflective film, the maximum value of the reflectance to EUV light with a wavelength in the vicinity of 13.5 nm is preferably 60% or higher, more preferably 65% or higher.

With a view to achieving high EUV light reflectance, the multilayer reflective film is generally in the form of a multilayer reflective film in which a high refractive index layer having a high refractive index to EUV light and a low refractive index layer having a low refractive index to EUV light are alternately stacked plural times.

Assuming a stacked unit in which a high refractive index layer and a low refractive index layer are stacked in this order from the substrate side as one cycle, the multilayer reflective film may have a laminated structure formed by a plurality of cycles. Assuming a stacked unit in which a low refractive index layer and a high refractive index layer are stacked in this order from the substate side, the multilayer reflective film may have a laminated structure formed by a plurality of cycles.

As the high refractive index layer, a layer containing Si can be used. Examples of the Si-containing material include not only elemental Si but also a Si compound containing Si and at least one selected from the group consisting of B, C, N and O. By the use of Si-containing high refractive index layers, the reflective mask can be obtained with high EUV light reflectance.

As the low refractive index layer, a layer containing a metal selected from the group consisting of Mo, Ru, Rh and Pt or an alloy thereof can be used.

In the high refractive index layer, Si is widely used. In the low refractive index layer, Mo is widely used. In other words, a Mo/Si multilayer reflective film is most commonly used. The multilayer reflective film is however not limited to this type. There can also be used a Ru/Si multilayer reflective film, a Mo/Be multilayer reflective film, a Mo compound/Si compound multilayer reflective film, a Si/Mo/Ru multilayer reflective film, a Si/Mo/Ru/Mo multilayer reflective film, a Si/Ru/Mo/Ru multilayer reflective film, a Si/Ru/Mo multilayer reflective film and the like.

The thickness of each of the layers and the number of repeating units of the layers constituting the multilayer reflective film are selected as appropriate depending on the film materials used and the EUV light reflectance required of the reflective film. Taking a Mo/Si multilayer reflective film as an example, to form the multilayer reflective film with a maximum EUV light reflectance of 60% or higher, Mo layers of 2.3±0.1 nm thickness and Si layers of 4.5±0.1 nm thickness may be alternately stacked such that the number of repeating units of these layers ranges from 30 to 60.

Each of the layers constituting the multilayer reflective film can be formed with a desired thickness by a known film formation method such as magnetron sputtering, ion beam sputtering or the like. To form the multilayer reflective film by e.g. ion beam sputtering, the sputtering is performed with the supply of ion particles from an ion source to a target of high refractive index material and to a target of low refractive index material. In the case where the multilayer reflective film is a Mo/Si multilayer reflective film, a Si layer of predetermined thickness is first formed on the substrate using a Si target, and then, a Mo layer of predetermined thickness is formed using a Mo target. Assuming such stacking of Si and Mo layers as one cycle, the Mo/Si multilayer reflective film is formed by 30 to 60 cycles of stacking.

### Multilayer Reflective Film-Protection Film

In the reflective mask blank of the present invention, the multilayer reflective film-protection film may be provided to, during patterning of the absorber film by an etching process (generally, dry etching process), protect the multilayer reflective film from damage by the etching process.

As the material capable of achieving the above purpose, a material containing at least one element selected from the group consisting of Ru, Rh and Si may be mentioned. The multilayer reflective film-protection film preferably contains at least one element selected from the group consisting of Ru and Rh.

More specifically, examples of the above-mentioned material include elemental Ru metal, a Ru alloy containing Ru and at least one metal selected from the group consisting of Si, Ti, Nb, Rh and Zr, Rh-based materials such as elemental Rh metal, a Rh alloy containing Rh and at least one metal selected from the group consisting of Si, Ti, Nb, Ru, Ta and Zr, a Rh-containing nitride containing the above-mentioned Rh alloy and nitrogen and a Rh-containing oxynitride containing the above-mentioned Rh alloy, nitrogen and oxygen, and the like

As the material capable of achieving the above purpose, there may also be mentioned Al, a nitride containing aluminum and nitrogen, Al₂O₃ and the like.

Among others, elemental Ru metal, a Ru alloy, elemental Rh metal or a Rh alloy is preferred as the material capable of achieving the above purpose. As the Ru alloy, a Ru—Si alloy is preferred. As the Rh alloy, a Rh—Si alloy is preferred.

The film thickness of the multilayer reflective film-protection film is not particularly limited so far as the multilayer reflective film-protection film performs its function. From the viewpoint of maintaining the rate of reflection of EUV light by the multilayer reflective film, the film thickness of the multilayer reflective film-protection film is preferably 1 to 10 nm, more preferably 1.5 to 6 nm, still more preferably 2 to 5 nm.

It is also preferable that: the material of the multilayer reflective film-protection film is elemental Ru metal, a Ru alloy, elemental Rh metal or a Rh alloy; and the film thickness of the multilayer reflective film-protection film is in the above-specified preferable thickness range.

The multilayer reflective film-protection film may be a single layer film or may be a multilayer film constituted by a plurality of layers. In the case where the multilayer reflective film-protection film is a multilayer film, each of the layers constituting the multilayer film is preferably formed of the above-mentioned preferable material. In the case where the multilayer reflective-film protection film is a multilayer film, the total film thickness of the multilayer film is preferably in the above-specified preferable protection film thickness range.

The multilayer reflective film-protection film can be formed by a known film formation method such as magnetron sputtering, ion beam sputtering or the like. In the case where a Ru film is formed by magnetron sputtering, the sputtering can preferably be performed using a Ru target as a sputtering target and Ar gas as a sputtering gas.

### Absorber Film

The absorber film in the reflective mask blank of the present invention is required to provide a high contrast between EUV light reflected by the multilayer reflective film and EUV light absorbed by the absorber film.

The patterned absorber film (absorber film pattern) may serve as a binary mask by absorption of EUV light, or may serve as a phase shift mask to reflect EUV light and provide a contrast by interference of the reflected light with EUV light from the multilayer reflective film.

In the case where the absorber film pattern is used as a binary mask, the absorber film needs to absorb EUV light and show a low EUV light reflectance. More specifically, when a surface of the absorber film is irradiated with EUV light, the maximum value of the reflectance to EUV light with a wavelength in the vicinity of 13.5 nm is preferably 2% or lower.

The absorber film may contain not only at least one metal selected from the group consisting of Ta, Ti, Sn and Cr, but also at least one component selected from the group consisting of O, N, B, Hf and H. Among other, the absorber film preferably contains N or B. By containing N or B, the crystalline state of the absorber film can be made amorphous or microcrystalline.

The crystalline state of the absorber film is preferably amorphous. In this case, the smoothness and flatness of the absorber film can be improved. When the smoothness and flatness of the absorber film are improved, the absorber film pattern can be reduced in edge roughness and improved in dimensional accuracy.

In the case where the absorber film pattern is used as a binary mask, the film thickness of the absorber film is preferably 40 to 70 nm, more preferably 50 to 65 nm.

In the case where the absorber film pattern is used as a phase shift mask, the EUV light reflectance of the absorber film is preferably 2% or higher. The EUV light reflectance of the absorber film is more preferably 9 to 15% to obtain a sufficient phase shift effect. When the absorber film is used as a phase shift mask, the contrast of an optical image on a wafer is improved, and the exposure margin is improved.

The material for forming the phase shift mask preferably contains a noble metal element. The noble metal element can be, for example, Ir, Pt, Pd, Ag, Os or Au.

Examples of the material for forming the phase shift mask include elemental Ru metal, a Ru alloy containing Ru and at least one metal selected from the group consisting of Cr, Au, Pt, Re, Hf, Ta, W, Ti and Si, an alloy of Ta and Nb, an oxide containing a Ru alloy or TaNb alloy and oxygen, a nitride containing a Ru alloy or TaNb alloy and nitrogen, an oxynitride containing a Ru alloy or TaNb alloy, oxygen and nitrogen, and the like.

Further, examples of the material for forming the phase shift mask include elemental Ir metal, an Ir compound containing Ir and at least one metal selected from the group consisting of Ta, Cr, Mo, W, Re and Si, and the like.

In the case where the absorber film pattern is used as a phase shift mask, the film thickness of the absorber film is preferably 30 to 60 nm, more preferably 35 to 55 nm.

The absorber film may be a single layer film or may be a multilayer film constituted by a plurality of layers. In the case where the absorber film is a single layer film, the number of steps in the production of the mask blank can be reduced to improve production efficiency. In the case where the absorber film is a multilayer film, the layer of the absorber film located opposite to the multilayer reflective film-protection film may be provided as an anti-reflective film layer for inspecting the absorber film pattern by irradiation with inspection light (e.g. light with a wavelength of 193 to 248 nm).

The absorber film can be formed by a known film formation method such as magnetron sputtering or ion beam sputtering. For example, in the case where a Ru oxide film is formed as the absorber film by magnetron sputtering, the sputtering for formation of the absorber film can be performed using a Ru target with the supply of a gas containing Ar gas and oxygen gas.

### Conductive Film

In the reflective mask blank of the present invention, the conductive film is arranged on the surface (second main surface) of the substrate opposite to the first main surface. With the arrangement of the conductive film, it becomes possible to handle the reflective mask blank by electrostatic chucking.

As the conductive film, an embodiment may be mentioned in which at least one first element selected from the group consisting of Cr and Ta is contained.

The conductive film contains at least one first element selected from the group consisting of Cr and Ta. The conductive film may contain at least one second element selected from the group consisting of B, C, N and O. However, the composition of the conductive film is different from the composition of the protection film as will be described later. Here, different compositions refer to not only the case where the conductive film and the protection film contain different elements, but also the case where the conductive film and the protection film contain the same two or more elements at different contents.

The conductive film preferably contains either one of Cr and Ta as the first element, and more preferably contains Cr. The conductive film preferably contains N as the second element. It is also preferable that the conductive film contains Cr as the first element and at least N as the second element.

Specific examples of the material for forming the conductive film include elemental Cr, CrN, CrO, CrON, CrB, CrBN, CrC, CrCN, CrOC, elemental Ta, TaN, TaO, TaON, TaB, TaBN, TaC, TaCN, TaOC, CrTaO, CrTaN and the like. Preferred is elementary Cr, CrN, TaN or TaBN. Here, the expression “CrON” refers to a material containing Cr, O and N where the contents of the respective elements are not particularly limited; and other materials can be expressed likewise.

In terms of the sheet resistance of the conductive film, it is preferable to not contain O as the second element.

The conductive film is preferably low in sheet resistance. The sheet resistance of the conductive film is, for example, preferably 200 Ω/sq. or lower, more preferably 100 Ω/sq. or lower.

The thickness of the conductive film is preferably 10 to 1000 nm, more preferably 100 to 500 nm.

The thickness of the conductive film is measured by X-ray reflectivity (XRR). The XRR thickness measurement of the conductive film is made with the use of SmartLab HTP manufactured by Rigaku Corporation. In this measurement, CuKα radiation is used as the X-ray source; the tube voltage is set to 40 kV; the tube current is set to 30 mA; and the analysis is performed using an attached software (GlobalFit).

Furthermore, the conductive film may have the function of adjusting stress on the second main surface side of the reflective mask blank. In other words, the conductive film may adjust the flatness of the reflective mask blank by balancing stresses from the respective films formed on the first main surface side.

The conductive film can be formed by a known film formation method such as a sputtering method e.g. magnetron sputtering or ion sputtering, a CVD method, a vacuum deposition method, or an electrolytic plating method.

In the case where a TaN film is used as the conductive film, the N content in the TaN film is preferably 10 at % or more to improve the hardness of the TaN film relative to the substrate. The N content in the TaN film is more preferably 15 at % or more, still more preferably 20 at % or more, particularly preferably 35 at % or more. The N content in the TaN film is preferably 65 at % or less to improve the surface smoothness of the TaN film and lower the sheet resistance of the TaN film. The N content in the TaN film is more preferably 60 at % or less, still more preferably 55 at % or less.

In the case where a TaB film is used as the conductive film, the B content in the TaB film is preferably 10 at % or more to improve the adhesion and surface smoothness of the film. The B content in the TaB film is more preferably 15 at % or more, still more preferably 20 at % or more. The B content in the TaB film is preferably 50 at % or less to improve the hardness of the film. The B content in the TaB film is more preferably 45 at % or less, still more preferably 40 at % or less.

In the case where a CrN film is used as the conductive film, the N content in the CrN film is preferably 3.0 at % or more to improve the hardness of the CrN film relative to the substrate. The N content in the CrN film is more preferably 3.5 at % or more, still more preferably 4.0 at % or more. The N content in the CrN film is preferably 20.0 at % or less to improve the surface roughness of the CrN film and lower the sheet resistance of the CrN film. The N content in the CrN film is more preferably 15.0 at % or less, still more preferably 10.0 at % or less, particularly preferably 9.0 at % or less.

### Protection Film

In the reflective mask blank of the present invention, the protection film is arranged on the surface of the conductive film opposite to the substrate.

As the protection film, there may be mentioned: an embodiment X in which Cr is contained; and an embodiment Y in which at least one first element A selected from the group consisting of Cr and Ta is contained.

In the embodiment X, the protection film contains Cr and at least one second element selected from the group consisting of B, C, N and O. The protection film preferably contains O as the second element.

Specific examples of the material for forming the protective film include CrN, CrO, CrON, CrB, CrBN, CrC, CrCN and CrOC. Here, the expression “CrON” refers to a material containing Cr, O and N where the contents of the respective elements are not particularly limited so far as the requirements for the later-described XPS analysis are satisfied; and other materials can be expressed likewise.

In the embodiment Y, the protection film contains at least one first element A selected from the group consisting of Cr and Ta and at least one second element selected from the group consisting of B, C, N and O. The protection film preferably contains either one of Cr and Ta, and more preferably contains Cr, as the first element A. The protection film preferably contains O as the second element. It is also preferable that the protection film contains Cr as the first element A and at least O as the second element.

Specific examples of the material forming the protection film include CrN, CrO, CrON, CrB, CrBN, CrC, CrCN, CrOC, TaN, TaO, TaON, TaB, TaBN, TaC, TaCN and TaOC. Here, the expression “CrON” refers to a material containing Cr, O and N where the contents of the respective elements are not particularly limited so far as the requirements for the later-described XPS analysis are satisfied; and other materials can be expressed likewise.

In the embodiment Y, it is preferable that the first element contained in the conductive film and the first element A contained in the protection film are the same element in terms of the adhesion between the conductive film and the protection film. Examples of this embodiment include: those in which the first element contained in the conductive film and the first element A contained in the protection film are Cr or Ta; and those in which the first element contained in the conductive film is Cr and the first element A contained in the protection film is Cr and Ta.

In the case where the first element contained in the conductive film is Ta, the protection film preferably contains Cr as the first element A in terms of the conductivity of the conductive film.

In the case where the first element contained in the conductive film is Ta, the protective film preferably contains Ta as the first element A in terms of the adhesion between the conductive film and the protection film.

The protection film (embodiment X) in the reflective mask blank of the present invention is formed such that, in XPS analysis of the protection film, a peak corresponding to the 2p_{3/2} orbital of Cr appears at 576.7 eV or lower. The peak corresponding to the 2p_{3/2} orbital of Cr preferably appears at 576.4 eV or lower, more preferably at 576.0 eV or lower, still more preferably at 575.5 eV or lower. Here, the peak corresponding to the 2p_{3/2} orbital of Cr normally appears at 573.2 eV or higher.

The method for XPS analysis and the method for calculating the binding energy of a peak corresponding to each orbital will be described later.

The protection film (embodiment Y) in the reflective mask blank of the present invention is formed such that, in XPS analysis of the protection film, a peak corresponding to the 2p_{3/2} orbital of Cr appears at 576.7 eV or lower or a peak corresponding to the 4f_{5/2} orbital of Ta appears at 23.8 eV or higher. In other words, when the conductive film contains Cr as the first element, a peak corresponding to the 2p_{3/2} orbital of Cr appears at 576.7 eV or lower; and, when the conductive film contains Ta as the first element, a peak corresponding to the 4f_{5/2} orbital of Ta appears at 23.8 eV or higher. Since the preferable range of the peak corresponding to the 2p_{3/2} orbital of Cr in this embodiment is the same as in the embodiment X, a description thereof will be omitted.

In the case where the peak corresponding to the 4f_{5/2} orbital of Ta appears at 23.8 eV or higher in the embodiment Y, the peak corresponding to the 4f_{5/2} orbital of Ta preferably appears at 29.0 eV or lower, more preferably at 28.9 eV or lower, still more preferably at 26.0 eV or lower, particularly preferably at 25.0 eV or lower.

The method for XPS analysis and the method for calculating the binding energy of a peak corresponding to each orbital will be described later.

The binding energy value of the peak corresponding to each orbital can be adjusted according to, for example, the type of the second element used and the ratio of the content of the second element to the total content of Cr (in the embodiment Y, the first element A) and the second element in the protection film. Preferred embodiments will be described later.

The protection film in the reflective mask blank of the present invention has a thickness of 2 nm or more. The thickness of the protection film is preferably 2 to 50 nm, more preferably 4 to 50 nm, still more preferably 5 to 50 nm, yet more preferably 7 to 50 nm, particularly preferably 10 to 50 nm, most preferably 10 to 30 nm.

The thickness of the protection film is measured by XRR.

In the present invention, the XPS analysis of the protection film is carried out by the following procedure.

In the XPS analysis, an analytical instrument “PHI 5000 VersaProbe” manufactured by ULVAC-PHI Inc. is used. This analytical instrument is calibrated according to JIS K0145.

First, a measurement sample of about 1 cm square is cut out from the reflective mask blank. The obtained measurement sample is set in a measurement holder in such a manner that the protection film serves as a measurement surface.

After the measurement holder is carried into the analytical instrument, a portion of the protection film up to 3 nm from the outermost surface is removed by irradiation with an argon ion beam. The sputtering rate during the removal can be measured using a separately prepared sample.

After the outermost surface portion of the protection film is sputtered away, the analysis is performed by irradiating the sputtered portion of the protection film with an X-ray (monochromatic AlK_{α} ray) at a photoelectron take-off angle (angle between the surface of the measurement sample and the direction of the detector) of 45°. During the analysis, charging-up is suppressed by using a flood gun.

As the analysis, the wide scan analysis is performed over a binding energy range of 1000 to 0 eV to confirm elements present, and then, the narrow scan analysis is performed in accordance with the elements (Cr or Ta, and C) present. The narrow scan analysis is performed under the conditions of, for example, a pass energy of 58.7 eV, an energy step of 0.1 eV, a time step of 50 ms and an accumulation number of 2 times.

Here, the calibration of the binding energy is conducted using the C 1 s orbital peak attributed to carbon present on the measurement sample. More specifically, the binding energy value of the C 1 s orbital peak of the measurement sample is obtained from the narrow scan analysis results, and then, a shift value is determined by subtracting the obtained binding energy value from 284.8 eV.

By adding the shift value to the binding energy value of each orbital peak obtained from the narrow scan analysis results, the binding energy value of the peak corresponding to the above-defined orbital is determined.

In the case where C is contained as a constituent component of the protection film, the calibration of the binding energy is conducted using Au whose surface has been cleaned in ultra-high vacuum. In this case, a shift value is determined by obtaining the binding energy value of the Au 4f_{7/2} orbital peak from the narrow scan analysis results and subtracting the obtained binding energy value from 83.96 eV.

When the binding energy value of each orbital peak is obtained from the narrow scan analysis results, the binding energy of the peak top is read as the binding energy value.

In the embodiment X or in the case where the protection film contains Cr as the first element A in the embodiment Y, the content of the second element in the protection film is preferably less than 65 atomic % to all the atoms in the protection film as determined by XPS analysis, more preferably 63 atomic % or less, still more preferably 60 atomic % or less, particularly preferably 45 atomic % or less, more particularly preferably 40 atomic % or less, most preferably 25 atomic % or less, with a view to achieving higher surface strength. Further, the content of the second element in the protection film is preferably 10 atomic % or more to all the atoms in the protection film, more preferably 15 atomic % or more.

The content of Cr (in the embodiment Y, the first element A) in the protection film is preferably 30 atomic % or more to all the atoms in the protection film as determined by XPS analysis, more preferably 40 atomic % or more, still more preferably 75 atomic % or more. Further, the content of the second element in the protection film is preferably 90 atomic % or less to all the atoms in the protection film.

Furthermore, the total content of Cr (in the embodiment Y, the first element A) and the second element in the protection film is preferably 80 atomic % or more to all the atoms in the protection film as determined by XPS analysis, more preferably 90 atomic % or more, still more preferably 95 atomic % or more. Further, the total content is preferably 100 atomic % or less to all the atoms in the protection film.

The contents of Cr (in the embodiment Y, the first element A) and of the second element are determined, from the wide scan spectra obtained by performing XPS analysis according to the above-mentioned procedure, with reference to the relative sensitivity coefficients specific to the respective elements and orbitals.

The ratio of the content of the second element to the total content of Cr (in the embodiment Y, the first element A) and the second element in the protection film is preferably 5 to 70 atomic %, more preferably 10 to 63 atomic %, still more preferably 10 to 60 atomic %, particularly preferably 10 to 40 atomic %, as determined by XPS analysis.

In the case where the protection film contains two or more types of second elements, the ratio of the total content of the second elements to the total content of Cr (in the embodiment Y, the first element A) and the second elements is preferably in the above-specified range.

In the case where only B is contained as the second element, the above-mentioned ratio is preferably 10 to 63 atomic %, more preferably 10 to 40 atomic %.

In the case where only C is contained as the second element, the above-mentioned ratio is preferably 10 to 63 atomic %, more preferably 10 to 40 atomic %.

In the case where only O is contained as the second element, the above-mentioned ratio is preferably 5 to 70 atomic %, more preferably 10 to 63 atomic %, still more preferably 10 to 60 atomic %, particularly preferably 10 to 40 atomic %.

In the case where only N is contained as the second element, the above-mentioned ratio is preferably 10 to 63 atomic %, more preferably 10 to 40 atomic %.

In the case where the protection film contains Ta in the embodiment Y, the content of the second element in the protection film is preferably 20 atomic % or more to all the atoms in the protection film as determined by XPS analysis, more preferably 30 atomic % or more, still more preferably 35 atomic % or more, particularly preferably 40 atomic % or more, with a view to achieving higher surface strength. Further, the content of the second element in the protection film is preferably 90 atomic % or less to all the atoms in the protection film, more preferably 80 atomic % or less, still more preferably 70 atomic % or less, particularly preferably 60 atomic % or less.

The contents of Ta and of the second element are determined, from the wide scan spectra obtained by performing the XPS analysis according to the above-mentioned procedure, with reference to the relative sensitivity coefficients specific to the respective elements and orbitals.

In the case where the protection film contains Ta in the embodiment Y, the content of Ta in the protection film is preferably 10 atomic % or more to all the atoms in the protection film as determined by XPS analysis, more preferably 20 atomic % or more, still more preferably 30 atomic % or more, yet more preferably 40 atomic % or more, particularly preferably 50 atomic % or more, more particularly preferably 60 atomic % or more. Further, the content of Ta in the protection film is preferably 80 atomic % or less to all the atoms in the protection film.

In the case where the protection film contains Ta in the embodiment Y, the ratio of the content of the second element to the total content of Ta and the second element in the protection film is preferably 20 to 90 atomic %, more preferably 30 to 80 atomic %, still more preferably 40 to 70 atomic %, as determined by XPS analysis.

In the case where the protection film contains Ta and two or more types of second elements in the embodiment Y, the ratio of the total content of the second elements to the total content of Ta and the second elements is preferably in the above-specified range.

In the case where only B is contained as the second element, the above-mentioned ratio is preferably 20 to 90 atomic %, more preferably 30 to 80 atomic %.

The ratio of the content of the second element to the total content of Ta (in the embodiment Y, the first element A) and the second element in the protection film is preferably 20 to 90 atomic %, more preferably 30 to 80 atomic %, still more preferably 35 to 70 atomic %, as determined by XPS analysis.

In the case where the protection film contains two or more types of second elements, the ratio of the total content of the second elements to the total content of Ta (in the embodiment Y, the first element A) and the second elements is preferably in the above-specified range.

In the case where only B is contained as the second element, the above-mentioned ratio is preferably 20 to 90 atomic %, more preferably 30 to 480 atomic %.

In the case where only C is contained as the second element, the above-mentioned ratio is preferably 20 to 90 atomic %, more preferably 30 to 480 atomic %.

In the case where only O is contained as the second element, the above-mentioned ratio is preferably 20 to 90 atomic %, more preferably 30 to 80 atomic %, still more preferably 40 to 70 atomic %, particularly preferably 40 to 60 atomic %.

In the case where only N is contained as the second element, the above-mentioned ratio is preferably 20 to 90 atomic %, more preferably 25 to 80 atomic %, still more preferably 30 to 70 atomic %, particularly preferably 35 to 60 atomic %.

The surface of the protection film opposite to the conductive film preferably has a surface roughness Rq of 0.450 nm or less, more preferably 0.350 nm or less. The lower limit of the surface roughness is not particularly limited, and may be 0 nm.

The surface roughness Rq refers to a root mean square height, and is synonymous with the root mean square height according to JIS B0681-2.

The measurement of the surface roughness Rq is done with a scanning probe microscope. More specifically, using “L-trace” manufactured by Hitachi High-Tech Corporation, surface observation is performed in dynamic force mode. The scanning range is set as a range of 2 μm square; the contact pressure is set to 20%; the vibration amplitude is set to 1.0 V; and the Q-curve is set to 3.00.

The volume resistivity of a laminated film of the conductive film and the protection film is preferably 8.0×10⁻¹ Ω·cm or lower, more preferably 2.0×10⁻² Ω·cm or lower, still more preferably 1.0×10⁻² Ω·cm or lower, particularly preferably 5.0×10⁻⁴ Ω·cm or lower, most preferably 2.0×10⁻⁴ Ω·cm or lower. The lower limit of the volume resistivity is not particularly limited, and is often 7.0×10⁻⁵ Ω·cm or higher.

The volume resistivity is measured with a low resistivity meter. The detailed measurement conditions are set in accordance with the measurement method used in the later-described Examples.

The hardness of the surface of the protection film opposite to the conductive film is preferably 10.0 GPa or higher, more preferably 15.0 GPa or higher. The surface hardness is generally 16.0 GPa or lower.

The surface hardness of the protection film is measured in a state where the conductive film and the protection film have been formed in this order on the substrate. The surface hardness measurement is made with the use of an iMicro nanoindenter manufactured by KLA Corporation. The detailed measurement conditions are set in accordance with the measurement method used in the later-described Examples.

### Other Film

The reflective mask blank of the present invention may have any other film. As the other film, a hard mask film may be mentioned. The hard mask film is preferably arranged on a side of the absorber film opposite to the reflective film-protection film.

The hard mask film is preferably a film made of a material having high resistance to dry etching, such as a Cr-based film or a Si-based film. The material of the Cr-based film can be, for example, Cr or a material containing Cr and at least one element selected from the group consisting of O, N, C and H. Specific examples of such a Cr-based material include CrO, CrN and the like. The material of the Si-based film can be Si or a material containing Si and at least one element selected from the group consisting of O, N, C and H. Specific examples of such a Si-based material include SiO₂, SiON, SiN, SiO, Si, SiC, SiCO, SiCN, SiCON and the like. By the formation of the hard mask film on the absorber film, the dry etching can be carried out even when the minimum line width of the absorber film pattern is reduced. The formation of the hard mask film is thus effective for miniaturization of the absorber film pattern.

### Method for Producing Reflective Mask and Reflective Mask

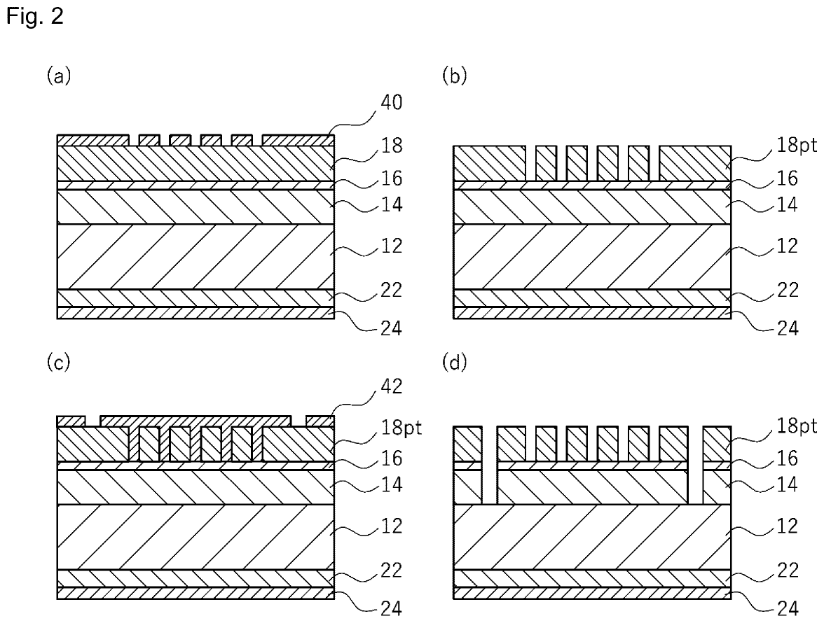

A reflective mask is obtained by patterning the absorber film of the reflective mask blank. An example of a method for producing the reflective mask will be described below with reference to FIG. 2.

Part (a) of FIG. 2 illustrates a state where a resist pattern 40 has been formed on the reflective mask blank in which the protection film 24, the conductive film 22, the substrate 12, the multilayer reflective film 14, the multilayer reflective film-protection film 16 and the absorber film 18 are arranged in this order. As a method for forming the resist pattern 40, a known method can be used. For example, the resist pattern A is formed by applying a resist to the absorber film 18 of the reflective mask blank and subjecting the applied resist to exposure and development. Herein, the resist pattern 40 corresponds to a pattern to be formed on a wafer by the use of the reflective mask.

After that, the absorber film 18 is patterned by etching using the resist pattern 40 shown in Part (a) of FIG. 2 as a mask, and then, the resist pattern 40 is removed to obtain a laminate with an absorber film pattern 18pt as shown in Part (b) of FIG. 2.

Subsequently, a resist pattern 42 is formed as shown in Part (c) of FIG. 2 so as to correspond to the frame of the exposure region on the laminate shown in Part (b) of FIG. 2. Dry etching is then performed using the resist pattern 42 shown in Part (c) of FIG. 2 as a mask. The dry etching is performed up to the substrate 12. The resist pattern 42 is removed after the dry etching, whereby the reflective mask is obtained as shown in Part (d) of FIG. 2.

The dry etching for formation of the absorber film pattern 18pt can be, for example, dry etching using Cl-based gas or dry etching using F-based gas.

The removal of the resist pattern 40 or 42 can be carried out by a known method such as removal by a cleaning liquid. Examples of the cleaning liquid include a sulfuric acid-hydrogen peroxide mixture (SPM), sulfuric acid, aqueous ammonia, an ammonia-hydrogen oxide mixture (APM), an OH-radical cleaning solution, ozonized water, and the like.

The reflective mask obtained by patterning the absorber film of the reflective mask blank of the present invention is suitable as a reflective mask used for EUV exposure. The reflective mask of the present invention has a back side surface excellent in strength.

### EXAMPLES

Now, the present invention will be described in further detail with reference to Examples.

The materials, amounts used, proportions and the like shown in the following Examples can be changed as appropriate without departing from the spirit and scope of the present invention. The present invention is therefore by no means restricted to the following Examples.

Here, Ex. 1 corresponds to Reference Example; Ex. 2 to 4, 8, 10 and 11 correspond to Examples of the present invention; and Ex. 5 to 7 and 9 correspond to Comparative Examples.

### Production of Samples

A sample of each Ex. was produced by forming a conductive film and a protection film in this order on a substrate.

The substrate used was a substrate of SiO₂—TiO₂ glass (with an external shape of 152 mm square, a thickness of about 6.3 mm and a chamfer width of 0.4 mm). This glass substrate had a thermal expansion coefficient of 0.2×10⁻⁷/° C., a Young's modulus of 67 GPa, a Poisson's ratio of 0.17 and a specific rigidity of 3.07×10⁷ m²/s². The glass substrate was used with a main surface of the glass substrate being polished to a surface roughness (root mean square height Sq) of 0.15 nm or less and a flatness of 100 nm or less.

A CrN layer with a thickness of 360 nm was formed, as the conductive film, by magnetron sputtering on a back side surface of the glass plate (opposite to the polished surface). The composition of the conductive film formed in Ex. 2 to 7 was analyzed by XPS and found to be Cr:N=92:8 (atomic ratio).

The film formation conditions of the conductive film were as follows.
Target: Cr target
Sputtering gas: mixed gas of Ar and N₂ (Ar: 60 vol %, N₂: 40 vol %)
Gas pressure: 0.04 Pa
Input power: 1800 W
Sputtering rate: 0.197 nm/s

In Ex. 1, the conductive film was formed using Ar gas as the sputtering gas.

A CrO layer with a thickness of 20 nm was formed, as the protection film, by magnetron sputtering on a side of the above-formed conductive film opposite to the substrate. The XPS analysis results of the thus-formed protection film are shown in the table below.

The term “metal” in the sputtering mode column of the table below means that the sputtering was performed under a condition that the surface of the target was in a metallic state (so-called metallic mode). On the other hand, the term “oxide” in the table below means that the sputtering was performed under a condition that the surface of the target was in an oxide state (so-called oxide mode). The term “nitride” in the table below means that the sputtering was performed under a condition that the surface of the target was in a nitride state (so-called nitride mode).

The film formation conditions of the protection film were as follows.
Target: Cr target
Sputtering gas: mixed gas of Ar and O₂ (the flow rates of the respective gases shown in the table below)
Gas pressure: shown in the table below
Input power: 1500 W
Sputtering temperature: 120° C.
Sputtering rate: 0.217 nm/s

In Ex. 1, no protection film was formed.

The sample of each Ex. was obtained according to the above-mentioned procedure.

### XPS Analysis

Each sample was analyzed by XPS according to the above-described method.

The binding energy obtained for each sample is shown in the table below.

### Resistivity

The resistivity was evaluated from the protection film-side surface of each sample under the following conditions. In this evaluation test, the volume resistivity of the laminated film of the conductive film and the protection film was measured.
Evaluation device: Loresta-GX manufactured by Nittoseiko Analytech Co., Ltd.
Measurement points: 9 points
Measurement range: 149 mm×149 mm

The resistivity measured for each sample is shown in the table below.

### Scratch Evaluation

The strength of the back side surface of each sample was evaluated under the following conditions.
Evaluation device: CSR5100 manufactured by Rhesca Co., Ltd.
Load condition: 0 to 300 mN
Increase of load: 5.0 mN/s
Scratch speed: 10 μm/s
Amplitude: 100 μm
Stylus diameter: 5 μm

The evaluation result of each sample is shown in the table below. In the table below, the strength of each Ex. is shown relative to the strength (strength of the back side surface) of Ex. 1 as 100%.

### Defect Evaluation

The number of defects in the protective film-side surface of each sample was evaluated under the following conditions.
Evaluation device: M1350 manufactured by Lasertec Corporation
Measurement area: 132 mm×132 mm

The evaluation result of each sample is shown in the table below.

### Surface Roughness

The surface roughness Rq of the protection film-side surface of each sample was evaluated according to the above-described method.

The surface roughness measured for each sample is shown in the table below.

### Surface Hardness

The surface hardness of the protection film of each sample was measured under the following conditions.
Evaluation device: iMicro Nanoindenter with high-resolution InForce 50 head manufactured by KLA Corporation
Indenter: Berkovich indenter
Maximum load: 50 mN
Stain rate: 0.2
Maximum load retention time: 2 seconds

In Ex. 8, a TaN film was formed as the conductive film by magnetron sputtering on one surface of the substrate; and a TaO film was formed by magnetron sputtering on a surface of the conductive film opposite to the conductive film.

The film formation conditions of each of the TaN film and the TaO film were as follows.

### TaN Film

Target: Ta target
Sputtering gas: mixed gas of Ar, N₂ and Kr (Ar: 76 vol %, N₂: 20 vol %, Kr: 4 vol %, gas pressure: 0.23 Pa)
Input power: 900 W
Sputtering rate: 0.083 nm/min

### TaO Film

Target: Ta target
Sputtering gas: mixed gas of Ar and O₂ (the flow rates of the respective gases shown in the table below)
Gas pressure: shown in the table below
Input power: 1000 W
Sputtering temperature: 120° C.
Sputtering rate: 0.15 nm/min

### Ex. 3 to 7

Conductive film-attached substrates were obtained in the same manner as in Ex. 2, except that the film formation conditions were changed as shown in the table below.

The measurement results are shown in the table below.

### Ex. 9 to 11

Conductive film-attached substrates were obtained in the same manner as in Ex. 8, except that the film formation conditions were changed as shown in the table below.

The measurement results are shown in the table below.

### Results

The configuration, film formation conditions, measurement results and evaluation results of the respective samples are shown in the table.

In the table, the term “sccm” refers to a flow rate at standard conditions and, more specifically, a flow rate in units of mL/min at 0° C. and atmospheric pressure.

In the table, the term “at %” refers to atomic %.

TABLE 1

| | | | Ex. 1 | Ex. 2 | Ex. 3 | Ex. 4 | Ex. 5 | Ex. 6 |
|---|---|---|---|---|---|---|---|---|
| Conductive film | Composition | Elements contained | Cr | CrN | CrN | CrN | CrN | CrN |
| | Film thickness [nm] | | — | 360 | 360 | 360 | 360 | 360 |
| Protection film | Composition | Elements contained | — | CrO | CrO | CrO | CrO | CrC |
| | | O content [at %] | 0 | 20 | 59 | 62 | 65 | 69 |
| | | N content [at %] | 0 | 0 | 0 | 0 | 0 | 0 |
| | Film formation | Sputtering mode | Metal | Metal | Metal | Metal | Metal | Oxide |
| | conditions | O₂ flow rate [sccm] | 0 | 20 | 45 | 75 | 90 | 25 |
| | | N₂ flow rate [sccm] | 0 | 0 | 0 | 0 | 0 | 0 |
| | | Ar flow rate [sccm] | 15 | 15 | 15 | 15 | 15 | 15 |
| | | Gas pressure [Pa] | 0.04 | 0.05 | 0.06 | 0.06 | 0.07 | 0.09 |
| | Binding energy [eV] | Cr 2p_{3/2} | 574.3 | 574.3 | 576.3 | 576.6 | 576.8 | 577.0 |
| | | Ta 4f_{5/2} | — | — | — | — | — | — |
| | Resistivity [Ω · cm] | | — | 9.3 × 10⁻⁵ | 1.1 × 10⁻⁴ | 1.2 × 10⁻⁴ | >1.0 × 10⁰ | >1.0 × 10⁰ |
| | Film thickness [nm] | | — | 20 | 20 | 20 | 20 | 20 |
| Evaluations | Scratch evaluation result [%] | | 100 | 114 | 118 | 105 | 89 | 9.9 |
| | Defect evaluation result | | — | 0 | 16 | 119 | >500 | >500 |
| | [number of defects] | | | | | | | |
| | Surface roughness [nm] | | 0.26 | 0.21 | 0.33 | 0.44 | 0.40 | 0.17 |
| | Surface hardness [Gpa] | | — | 19.7 | 19 | 11 | — | — |
| | | | Ex. 7 | Ex. 8 | Ex. 9 | Ex. 10 | Ex. 11 | |
| Conductive film | Composition | Elements contained | CrN | TaN | TaN | TaN | TaN | |
| | Film thickness [nm] | | 360 | 62 | 62 | 62 | 62 | |
| Protection film | Composition | Elements contained | CrO | TaO | Ta | TaO | TaN | |
| | | O content [at %] | 68 | 42 | 0 | 65 | 0 | |
| | | N content [at %] | 0 | 0 | 0 | 0 | 40 | |
| | Film formation | Sputtering mode | Oxide | Metal | Metal | Oxide | Oxide | |
| | conditions | O₂ flow rate [sccm] | 45 | 21 | 0 | 40 | 0 | |
| | | N₂ flow rate [sccm] | 0 | 0 | 0 | 0 | 50 | |
| | | Ar flow rate [sccm] | 15 | 14 | 50 | 10 | 40 | |
| | | Gas pressure [Pa] | 0.13 | 0.06 | 0.17 | 0.05 | 0.25 | |
| | Binding energy [eV] | Cr 2p_{3/2} | 576.9 | — | — | — | — | |
| | | Ta 4f_{5/2} | — | 24.0 | 23.7 | 28.7 | 25.0 | |

| | | | | | | |
|---|---|---|---|---|---|---|
| | Resistivity [Ω · cm] | >1.0 × 10⁰ | 1.2 × 10⁻² | | >1.0 × 10⁰ | |
| | Film thickness [nm] | 20 | 10 | 10 | 10 | 10 |
| Evaluations | Scratch evaluation result [%] | 0.6 | 183 | 122 | 124 | 123 |
| | Defect evaluation result | >500 | — | | | |
| | [number of defects] | | | | | |
| | Surface roughness [nm] | 0.18 | 0.49 | | | |
| | Surface hardness [Gpa] | — | 10.6 | | | |

As confirmed from the results of Table 1, the surface (back side surface) of the reflective mask blank sample on the back side where the conductive film was arranged was high in strength in Ex. 2 to 4 and 8 in which the protection film was formed to satisfy the binding energy requirement. On the other hand, the back side surface was low in strength in Ex. 5 to 7 in which the binding energy requirement was not satisfied and in Ex. 1 in which no protection film was provided.

It was also confirmed that the surface on the back side (back side surface) was higher in strength in Ex. 8, 10 and 11 in which the protection film was formed to contain Ta and satisfy the binding energy requirement than in Ex. 9 in which the binding energy requirement was not satisfied.

It was further confirmed from comparison of Ex. 2 and Ex. 3 that better surface roughness and higher resistivity were obtained when the content of the second element (O) was 40 atomic % or less to all the atoms in the protection film.

The reflective mask blank of the present invention can be obtained by forming a multilayer reflective film and an absorber film as described above on a surface of each of the samples of Ex. 2 to 4, 8, 10 and 11 opposite to the conductive film.

This application is a continuation of PCT Application No. PCT/JP2023/037235, filed on Oct. 13, 2023, which is based upon and claims the benefit of priority from Japanese Patent Application No. No. 2022-169168 filed on Oct. 21, 2022 and Japanese Patent Application No. 2023-085943 filed on May 25, 2023. The contents of those applications are incorporated herein by reference in their entireties.

### REFERENCE SYMBOLS

10: Reflective mask blank
12: Substrate
14: Multilayer reflective film
16: Multilayer reflective film-protection film
18: Absorber film
18pt: Absorber film pattern
22: Conductive film
24: Protection film
40, 42: Resist pattern

What is claimed is:

1. A reflective mask blank, comprising:
a substrate;
a conductive film arranged on one surface side of the substrate;
a protection film arranged on a side of the conductive film opposite to the substrate;
a multilayer reflective film to reflect EUV light, arranged on the other surface side of the substrate; and
an absorber film arranged on a side of the multilayer reflective film opposite to the substrate,
wherein the conductive film and the protection film have different compositions,
wherein the conductive film contains a first element selected from the group consisting of chromium and tantalum,
wherein the protection film contains chromium and at least one second element selected from the group consisting of boron, carbon, nitrogen and oxygen,
wherein the protection film has a thickness of 2 nm or more, and
wherein, in X-ray photoelectron spectroscopy analysis of the protection film, a peak corresponding to the 2p_{3/2} orbital of chromium appears at 576.7 eV or lower.

2. A reflective mask blank, comprising:
a substrate;
a conductive film arranged on one surface side of the substrate;
a protection film arranged on a side of the conductive film opposite to the substrate;
a multilayer reflective film to reflect EUV light, arranged on the other surface side of the substrate; and
an absorber film arranged on a side of the multilayer reflective film opposite to the substrate,
wherein the conductive film and the protection film have different compositions,
wherein the conductive film contains a first element selected from the group consisting of chromium and tantalum,
wherein the protection film contains a first element A selected from the group consisting of chromium and tantalum and at least one second element selected from the group consisting of boron, carbon, nitrogen and oxygen,
wherein the protection film has a thickness of 2 nm or more, and
wherein, in X-ray photoelectron spectroscopy analysis of the protection film, a peak corresponding to the 2p_{3/2} orbital of chromium appears at 576.7 eV or lower, or a peak corresponding to the 4f_{5/2} orbital of tantalum appears at 23.8 eV or higher.

3. The reflective mask blank according to claim 1,
wherein the protection film contains chromium, and
wherein the content of the second element in the protection film is 10 to 65 atomic % to all atoms in the protection film as determined by X-ray photoelectron spectroscopy analysis.

4. The reflective mask blank according to claim 3, wherein the content of the second element in the protection film is 63 atomic % or less to all atoms in the protection film as determined by X-ray photoelectron spectroscopy analysis.

5. The reflective mask blank according to claim 3, wherein the content of the second element in the protection film is 40 atomic % or less to all atoms in the protection film as determined by X-ray photoelectron spectroscopy analysis.

6. The reflective mask blank according to claim 2,
wherein the protection film contains tantalum, and
wherein the content of the second element in the protection film is 20 atomic % or more to all atoms in the protection film as determined by X-ray photoelectron spectroscopy analysis.

7. The reflective mask blank according to claim 2, wherein the content of the second element in the protection film is 20 to 90 atomic % to all atoms in the protection film as determined by X-ray photoelectron spectroscopy analysis.

8. The reflective mask blank according to claim 1, wherein the second element contained in the protection film includes at least oxygen.

9. The reflective mask blank according to claim 1, wherein the conductive film includes at least nitrogen as a second element.

10. The reflective mask blank according to claim 1, wherein the protection film has a surface roughness Rq of 0.450 nm or less.

11. The reflective mask blank according to claim 1, wherein the protection film has a thickness of 2 to 50 nm.

12. The reflective mask blank according to claim 1, wherein the protection film has a thickness of 10 to 50 nm.

13. The reflective mask blank according to claim 1, wherein a laminated film of the protection film and the conductive film has a volume resistivity of 2.0×10⁻² Ω·cm or lower.

14. The reflective mask blank according to claim 1, wherein a laminated film of the protection film and the conductive film has a volume resistivity of 2.0×10⁻⁴ Ω·cm or lower.

15. The reflective mask blank according to claim 1, wherein the protection film has a surface hardness of 10.0 GPa or higher.

16. A reflective mask comprising an absorber film pattern formed by pattering the absorber film of the reflective mask blank as defined in claim 1.

17. A method for producing a reflective mask blank, comprising patterning the absorber film of the reflective mask blank as defined in claim 1.

18. A method for producing the reflective mask blank as defined in claim 1, comprising:
forming the conductive film on one surface side of the substrate; and
forming the protection film on a surface of the conductive film opposite to the substrate,
wherein the formation of the protection film is performed in the presence of at least one type of gas selected from the group consisting of oxygen gas and nitrogen gas.

19. The method for producing the reflective mask blank according to claim 18,
wherein the protection film is formed using a sputtering target,
wherein the sputtering target contains a first element A selected from the group consisting of chromium and tantalum,
wherein a surface of the sputtering target is mainly in a metallic state.
